(19) United States
(12) Patent Application Publication
(10) Pub. No.: US 2026/0279734 A1
(43) Pub. Date: Sep. 17, 2026

(54) SYSTEMS AND METHODS FOR CONTROLLING A SUPPLY OF MULTIPLE GASES TO A PLASMA CHAMBER

(71) Applicant: Lam Research Corporation, Fremont, CA (US)

(72) Inventors: Andrew Stratton Bravo, Piedmont, CA (US); Butch Berney, Pleasanton, CA (US); Gerome Michel Dominique Melaet, San Leandro, CA (US); Julien Augustin Monbeig, Hillsboro, OR (US)

(21) Appl. No.: 19/168,307

(22) PCT Filed: Mar. 20, 2024
(86) PCT No.: PCT/US2024/020755

§ 371 Date: Sep. 23, 2025

Related U.S. Application Data
(60) Provisional application No. 63/455,229, filed on Mar. 28, 2023.

(51) Int. Cl. H01J 37/32

(52) U.S. Cl. CPC H01J 37/32449

(57) ABSTRACT

Systems and methods for supplying multiple gases are described. One of the systems includes a gas adapter having a plenum. The system further includes a first gas line coupled to the gas adapter for transfer of a first process gas to the plenum. The system includes a second gas line coupled to the gas adapter for transfer of a second process gas to the plenum. The first and second process gases are transferred while maintaining temperatures of the first and second process gases. The gas adapter mixes the first process gas with the second process gas under vacuum to generate a gas mixture for supply of the gas mixture to an inside volume of a plasma chamber.

### FIELD

The present embodiments relate to systems and methods for controlling a supply of multiple gases to a plasma chamber.

### BACKGROUND

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A chamber includes an electrostatic chuck enclosed within a volume of the chamber. On top of the electrostatic chuck, a semiconductor wafer is placed. Thereafter, one or more gases are supplied to the volume of the chamber to etch the semiconductor wafer. However, the semiconductor wafer is not etched in a desirable manner.

### SUMMARY

Embodiments of the disclosure provide systems, apparatus, methods and computer programs for controlling a supply of multiple gases to a plasma chamber. It should be appreciated that the present embodiments can be implemented in numerous ways, e.g., a process, an apparatus, a system, a device, or a method on a computer readable medium. Several embodiments are described below.

In one embodiment, hardware allows only one gas line to deliver all chemistries, such as multiple gases, to a chamber regardless of thermal only or plasma process. This can pose safety issues since the gases mix upstream of the chamber, either in a gas box or in a delivery line. It has been found that the gases, such as Fluorine (F₂) and Hydrogen (H₂), produce an exothermic reaction inside the gas box or the delivery line.

In an embodiment, a selective removal of a stack layer, such as Silicon Germanium (SiGe) or another layer, is important for device fabrication. In general, a process, for the selective removal uses a gas mixture, such as 20% Fluorine (F₂) and 80% Argon (Ar) or another gas mixture. The Fluorine in this mixture is used in a thermal reaction to remove the stack layer. Adding other chemistries, such as Hydrogen, can adjust parameters, such as selectivity and uniformity, during the selective removal. The systems and methods, described herein, allow for an independent and interlocked flow of Fluorine-based gases, and other gases, such as Hydrogen-based gases. The systems include a dual injector that is placed on top of a gas diffuser for a plasma reactor. This reduces a safety concern by mixing the gases in the plasma reactor and under vacuum instead of in the as box or in the delivery line.

In one embodiment, a system for supplying multiple gases to a plasma chamber is described. The system includes a gas adapter having a body, a first hole formed inside the body, a second hole formed inside the body, and a plenum. The system further includes a first gas line coupled to the gas adapter at an opening of the first hole. The first gas line transfers a first process gas to the plenum via the first hole. The system also includes a second gas line coupled to the gas adapter via an opening of the second hole. The second gas line transfers a second process gas to the plenum via the second hole. The first process gas is transferred via the first gas line and the second process gas is transferred via the second gas line while maintaining a first temperature of the first process gas to be within a first predetermined range and a second temperature of the second process gas to be within a second predetermined range. The first and second temperatures are lower than a third temperature that is achieved by a mixture, at an atmospheric pressure, of the first process gas with the second process gas. The gas adapter mixes the first process gas with the second process gas under vacuum to generate a gas mixture for supply of the gas mixture to an inside volume of the plasma chamber.

In one embodiment, a method for supplying multiple gases to a plasma reactor for processing a substrate is described. The method includes receiving a first process gas from a first gas line. The first process gas is received by a gas adapter coupled to the first gas line. The method includes transferring the first process gas from the gas adapter via a diffuser to a volume of the plasma reactor to etch a first portion of a stack layer of the substrate. The method further includes obtaining, the first process gas from the first gas line and a second process gas from a second gas line after receiving the first process gas via the first gas line. The first process gas is obtained via the first gas line and the second process gas is obtained via the second gas line by the gas adapter coupled to the second gas line. The first process gas is obtained from the first gas line and the second process gas is obtained from the second gas line while simultaneously maintaining a first temperature of the first process gas and a second temperature of the second process gas to be within a first predetermined range. The first and second temperatures are lower than a third temperature that is achieved by mixing, at an atmospheric pressure, the first process gas with the second process gas. The method also includes mixing, within the gas adapter, the first and second process gases under vacuum to generate a gas mixture. The method includes supplying the gas mixture from the gas adapter via the diffuser to the volume of the plasma reactor to etch a second portion of the stack layer.

In an embodiment, a plasma system for supplying multiple gases to a plasma chamber is described. The plasma system includes a gas box, a gas adapter, and a first gas line coupled to the gas adapter and to the gas box. The first gas line transfers a first process gas. The plasma system further includes a second gas line coupled to the gas adapter and to the gas box. The second gas line transfers a second process gas. The first process gas is transferred via the first gas line and the second process gas is transferred via the second gas line while maintaining a first temperature of the first process gas and a second temperature of the second process gas to be within a predetermined range. The first and second temperatures are lower than a third temperature that is achieved by a mixture, at an atmospheric pressure, of the first process gas with the second process gas. The gas adapter mixes the first process gas with the second process gas under vacuum to generate a gas mixture for supply of the gas mixture to an inside volume of the plasma chamber.

Some advantages of the herein described systems and methods include providing separate flow of two reactive process gases via two separate gas lines to a gas adapter. By providing the separate flow, the process gases do not react with each other under atmospheric pressure but rather mix with each other under vacuum within a plenum of the gas adapter to form a gas mixture. The gas mixture is transferred from the plenum via a diffuser to a volume of a plasma reactor to process a substrate.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system to illustrate gas lines that are coupled to a gas adapter.

FIG. 2 is a diagram of an embodiment of a plasma system to illustrate functionality of the plasma system.

FIG. 3 is an embodiment of a graph to illustrate the first and second predetermined ranges of temperatures at which process gases flow in different gas lines.

FIG. 4 is a diagram of an embodiment of a system to illustrate that a temperature of a process gas is maintained to be within the first predetermined range with an increase in a flow of the process gas and a temperature of another process gas is maintained to be within the second predetermined range with an increase in a flow of the other process gas.

FIG. 5A is a diagram of an embodiment of a substrate before the substrate is thermally processed using the plasma system of FIG. 2.

FIG. 5B is a diagram of an embodiment of a substrate to illustrate etching of the substrate of FIG. 5A by using a process gas.

FIG. 5C is a diagram of an embodiment of a substrate to illustrate etching of the substrate of FIG. 5B by using the gas mixture.

FIG. 6 is a flowchart of an embodiment of a method to illustrate processing of a substrate of FIG. 1 by applying a process gas and the gas mixture.

### DETAILED DESCRIPTION

The following embodiments describe systems and methods for controlling a supply of multiple gases to a plasma chamber. It will be apparent that the present embodiments may be practiced without some or all of these specific details. In other instances, well known process operations have not been described in detail in order not to unnecessarily obscure the present embodiments.

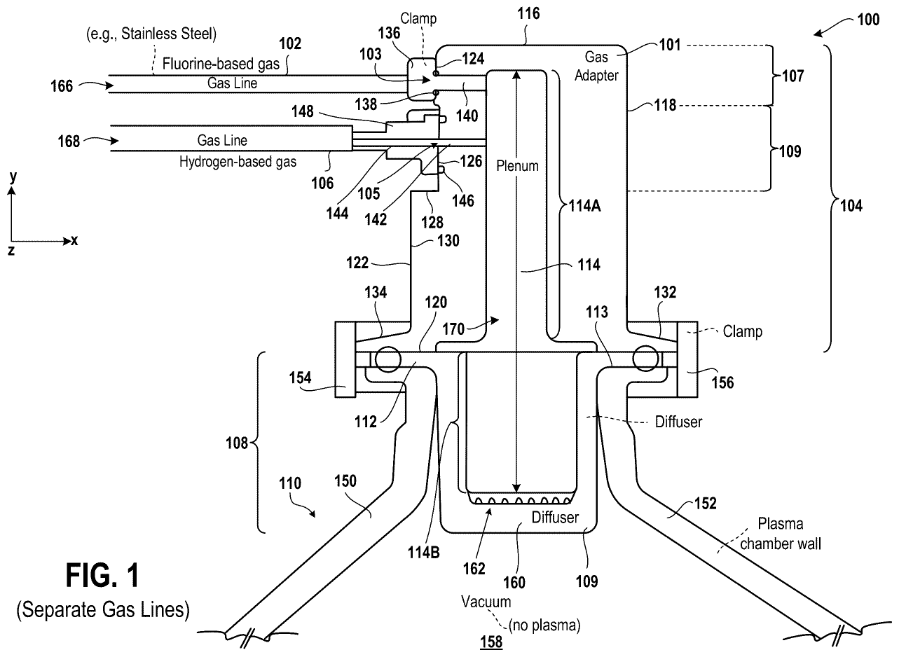

FIG. 1 is a diagram of an embodiment of a system 100 to illustrate a gas line 102 that is coupled to a gas adapter 104. The system 100 and includes the gas line 102, the gas adapter 104, another gas line 106, a diffuser 108, and a plasma chamber 110. An example of the gas line 102 is a tube or a pipe fabricated from one of more metals, such as stainless steel. Also, an example of the gas line 106 is a tube that is a tube or a pipe fabricated from one of more metals, such as stainless steel.

An example of the gas adapter 104 is a seal that seals the diffuser 108 at a left side flange portion 112 and a right side flange portion 113 of the diffuser 108 to form a plenum 114 that is enclosed by a body 101 of the gas adapter 104 and by a body 109 of the diffuser 108. To illustrate, each of the gas adapter 104 and the diffuser 108 is fabricated from a dielectric material, such as quartz. The flange portions 112 and 113 form a flange, such as a rim or a collar, of the gas adapter 104. It should be noted that the terms body and housing are used herein interchangeably.

The body 101 includes a top wall 116, a right wall 118, a bottom wall 120, and a left wall 122. As an example, a portion of the body 101 extends horizontally between the walls 122 and 118 and vertically between the walls 116 and 120, and the body 101 includes the flange of the gas adapter 104. The bottom wall 120 is a wall of the flange of the gas adapter 104. The left wall 122 includes a first portion 124, a second portion 126, a third portion 128, and a fourth portion 130. An example of each of the portions 124, 126, 128, and 130 is a surface. The first portion 124 is vertically oriented in a direction of a y-axis, the second portion 126 is also vertically oriented, and the fourth portion 130 is also vertically oriented. The third portion 128 is horizontally oriented in a direction of an x-axis, which is perpendicular to the y-axis. The first portion 124 extends from the top wall 116 to a horizontal level of the second portion 126. The second portion 126 extends from a horizontal level of the first portion 124 to the third portion 128. The third portion 128 extends from the second portion 128 to the fourth portion 130.

Also, the second portion 126 is located inward, such as indented, compared to the first portion 124 and the fourth portion 130 to form a concave cavity with respect to the portions 124 and 130 in the direction of the x-axis. A z-axis is perpendicular to each of the x and y axes. The top wall 116 is horizontally oriented, the right wall 118 is vertically oriented and the bottom wall 120 is horizontally oriented.

It should be noted that a component, such as a portion or a wall or a hole or a section or a part or an extension, is vertically oriented when the component is in the direction of the y-axis. For example, the component is in the direction of the y-axis when the component extends along the y-axis. To illustrate, the component extends along the y-axis when the component is parallel or substantially parallel to the y-axis. In the illustration, the component is substantially parallel to the y-axis and the component forms an angle between 0 degrees and 10 degrees with respect to the y-axis.

It should further be noted that a component, such as a portion or a wall or a hole or a section or an extension, as described herein, is horizontally oriented when the component is in the direction of the x-axis. For example, the component is in the direction of the x-axis when the component extends along the x-axis. To illustrate, the component extends along the when the component is parallel or substantially parallel to the x-axis. In the illustration, the component is substantially parallel to the x-axis when the component forms an angle between 0 degrees and 10 degrees with respect to the x-axis.

The top wall 116 is contiguous with and adjacent to the right wall 118 and the left wall 122. Between the bottom wall 120 and the right wall 118 is a right side flange portion 132 of the gas adapter 104. Also, between the bottom wall 120 and the left wall 122 is a left side flange portion 134 of the gas adapter 104. The flange portions 132 and 134 form a flange of the gas adapter 104. The left side flange portion 134 is contiguous with and adjacent to the left wall 122, and is contiguous with an adjacent to the bottom wall 120. The left side flange portion 134 extends along the x-axis from the left wall 122. Similarly, the right side flange portion 132 is contiguous with and adjacent to the right wall 118, and is contiguous with an adjacent to the bottom wall 120. The right side flange portion 132 extends along the x-axis from the right wall 118. Within the gas adapter 104, a top portion 114A of the plenum 114 is formed and within the diffuser 108, a bottom portion 114B of the plenum 114 is formed.

The plenum 114 is vertically oriented within the gas adapter 104 and the diffuser 108. For example, the top portion 114A is vertically oriented in the gas adapter 104 and the bottom portion 114B is vertically oriented in the diffuser 108.

The gas line 102 is coupled via a hole 140 to the top portion 114A. For example, the hole 140 interfaces at one end, such as an opening 103, with the gas line 102 and at an opposite end to the top portion 114A. In the example, the opening 103 is of the hole 140 that is horizontally oriented and extends within the body 101 of the gas adapter 104. To illustrate, the gas line 102 is coupled via a connector system, such as a clamp 136 and an O-ring 138, to the opening 103 to be coupled to the gas adapter 104 at the opening 103. As another illustration, the O-ring 138 encircles an extension of the gas adapter 104, the gas line 102 extends over the O-ring 138, and the clamp 136 extends over the gas line 102 to couple the gas line 102 to the gas adapter 104. In the illustration, the extension of the gas adapter 104 is horizontally oriented. As yet another illustration, a connector system, such as a connector gas line (not shown), such as a pipe or a tube or a hollow extension, is coupled between the gas line 102 and the hole 140 to couple the gas line 102 to the hole 140. To further illustrate, the O-ring 138 fits around a first end of the connector gas line, the first end of the connector gas line extends into the hole 140 to fit to the hole 140 via the O-ring 138, another O-ring (not shown) fits around a second end of the connector gas line, and the second end of the connector gas line extends into a hollow of the gas line 102 to fit to the gas line 102 via the other O-ring (not shown) to interface the gas line 102 to with the connector gas line. An O-ring is an example of a fitting.

It should be noted that the hole 140 is not a through hole that extends along a width of the body 101 of the gas adapter 104. As an example, the width extends horizontally from the left wall 122 to the right wall 118. Further, in the example, the hole 140 extends from the left wall 122 to the top portion 114A. To illustrate, the hole 140 is drilled into the body 101. As another illustration, the body 101 is molded in a molding machine to have the hole 140.

The hole 140 is horizontally oriented to interface with the top portion 114A of the plenum 114 to open into the plenum 114. For example, the hole 140 is contiguous with the top portion 114A of the plenum 114 to form an opening into the plenum 114.

Similarly, the gas line 106 is coupled via a hole 142 to the top portion 114A. For example, the hole 142 interfaces at one end, such as an opening 105, with a connection gas line 144, which is coupled to the gas line 106, and interfaces at an opposite end to the top portion 114A. In the example, the opening 105 is of the hole 142 horizontally oriented inside the body 101 of the gas adapter 104. To illustrate, the gas line 106 is coupled via a connector system, such as the connection gas line 144, an O-ring 146, and a clamp 148, to the opening 105 to be coupled to the gas adapter 104 at the opening 105. As another illustration, the connector system is coupled between the gas line 106 and the hole 142 to couple the gas line 106 to the hole 142. As yet another illustration, the O-ring 146 extends into a groove formed within the body 101 of the gas adapter 104 and the clamp 148 extends around the connection gas line 144 and the O-ring 146 to clamp the connection gas line 144 to the hole 142. As yet another illustration, the connection gas line 144 is coupled at one end via an O-ring (not shown) to the gas line 106 to interface with the gas line 106. The hole 142 is located vertically below the hole 140.

It should be noted that the hole 142 is not a through hole that extends along the width of the body 101 of the gas adapter 104. Further, in the example, the hole 142 extends from the left wall 122 to the top portion 114A. To illustrate, the hole 142 is drilled into the body 101. As another illustration, the body 101 is molded in the molding machine to have the hole 142.

It should be noted that the clamp 136 is fitted to the first portion 124 of the left wall 122 and the clamp 148 is fitted to the second portion 126 of the left wall 122. For example, the clamp 148 is adjacent to the clamp 136. It should further be noted that the gas line 102 is adjacent to the gas line 106. For example, there are no other gas lines between the two gas lines 102 and 106.

The hole 142 is horizontally oriented to interface with the top portion 114A to open into the plenum 114. For example, the hole 142 is contiguous with the top portion 114A to form an opening into the plenum 114.

The body 101 includes a body portion 107 and a body portion 109. The body portion 107 includes the first portion 124, a portion of the right wall 118, the hole 140 and a first section of the top portion 114A. The body portion 109 includes the second portion 126, a portion of the right wall 118, the hole 142, and a second section of the top portion 114A. The body portion 107 is located above the body portion 109 and is integral to the body portion 109.

It should be noted that the hole 142 is parallel to or substantially parallel to the hole 140. To illustrate, the hole 142 is substantially parallel to the hole 140 when the hole 140 forms an angle between 0 degrees and 10 degrees with respect to the hole 142.

The flange of the gas adapter 118 is connected to the flange of the diffuser 108 to form the plenum 114 that is contiguous across a height of the diffuser 108 and a height of the gas adapter 104. A height, as used herein, is measured along the y-axis.

Below the flange of the diffuser 108 is a left portion 150 of a wall of the plasma chamber 110 and a right portion 152 of the wall. The flange of the diffuser 108, the flange of the gas adapter 104, and the wall of the plasma chamber 110 are fitted and held together by a clamp 154 and a clamp 156.

The bottom portion 114B of the plenum 114 and the diffuser 108 extends into an inside volume 158 of the plasma chamber 110. A bottom wall 160 of the diffuser 108 has multiple openings 162, such as outlets or holes, that extend via the bottom wall 160 to open to the inside volume 158 of the plasma chamber 110.

A vacuum is created within the inside volume 158 of the plasma chamber 110. For example, a vacuum pump, described below, creates the vacuum in the inside volume 158. The vacuum created within the inside volume 158 extends into the plenum 114. After the vacuum is created within the inside volume 158 and the plenum 114, a process gas 166 is transferred via the gas line 102, the opening 103, and the hole 140 into the top portion 114A of the plenum 114 and another process gas 168 is transferred via the gas line 106, the connection gas line 144, the opening 105, and the hole 142 into the top portion 114A. An example of the process gas 166 is a Fluorine-containing gas, such as nitrogen trifluoride (NF₃), carbon tetrafluoride (CF₄), sulfur hexafluoride (SF₆), silicon tetrafluoride (SiF₄), Fluorine (F₂), and Fluorine mixed with Argon. To illustrate, a mix of Fluorine and Argon includes 20 percent (%) Fluorine and 80% Argon. An example of the process gas 168 is a Hydrogen-containing gas, such as Methane (CH₄), Ethane (C₂H₆), Propane (C₃H₈), Butane (C₄H₁₀), and Hydrogen (H₂). It should be noted that the terms Fluorine-containing gas and Fluorine-based gas are used herein interchangeably, and the terms Hydrogen-containing gas and Hydrogen-based gas are used herein interchangeably.

The process gases 166 and 168 are highly reactive with each other under atmospheric pressure. To illustrate, under atmospheric pressure, such as a pressure of 1 atmospheric pressure (atm), the process gas 166 mixes or reacts with the process gas 168 to create an exothermic reaction to release a large amount of heat.

The process gases 166 and 168 are received simultaneously via the gas lines 102 and 106 and the holes 140 and 142 by the gas adapter 104 and mix with each other in the top portion 114A of the plenum 114 to form a gas mixture 170 under vacuum within the plenum 114. An example of the gas mixture 170 is a mixture of the Fluorine-containing and the Hydrogen-containing gas. To illustrate, the gas mixture 170 is Fluoromethane (CH₃F). The gas mixture 170 flows from the top portion 114A to the bottom portion 114B of the plenum 114 in a vertical along the y-axis, and exits from the diffuser 108 via the openings 162 to the inside volume 158 of the plasma chamber 110. The inside volume 158 is under vacuum when the gas mixture 170 exits into the inside volume 158 from the diffuser 108.

In one embodiment, the process gas 168 is transferred via the gas line 102 and the process gas 166 is transferred via the gas line 106.

In an embodiment, one or more of the gas lines 102 and 106 are bent at one or more portions of the gas line.

In one embodiment, the gas lines 102 and 106, the clamps 136 and 148, and the holes 140 and 142 are sometimes referred to herein as a dual gas injector.

In an embodiment, the gas lines 102 and 106, the clamps 136 and 148, and the holes 140 and 142 and the portion 114A are sometimes referred to herein as a dual gas injector.

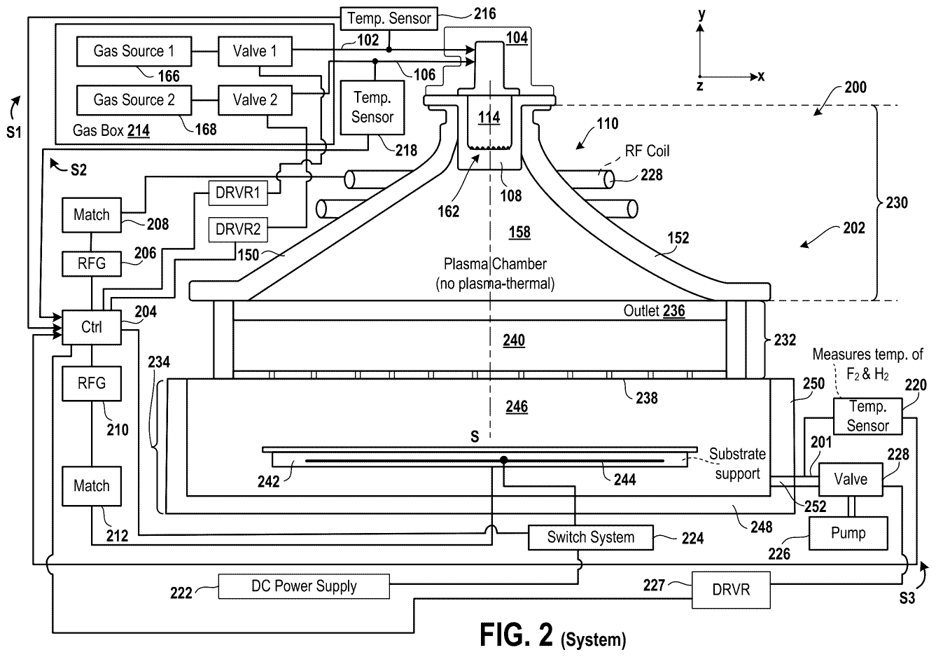

FIG. 2 is a diagram of an embodiment of a plasma system 200 to illustrate functionality of the plasma system 200. The plasma system 200 includes a plasma reactor 202, a controller 204, a source radio frequency (RF) generator 206, a match 208, a bias RF generator 210, a match 212, a gas box 214, a temperature sensor 216, another temperature sensor 218, a temperature sensor 220, a direct current (DC) power supply 222, a switch system 224, a vacuum pump 226, a driver 227, and a valve 228.

An example of a gas source is a container or a volume enclosure. Also, an example of a gas box is a container or a volume enclosure. An example of a controller includes a processor and a memory device. To illustrate, functions described herein by the controller 104 are performed by the processor of the controller 104. The processor of the controller is coupled to the memory device of the controller. Examples of the match, as used herein, include an impedance matching circuit and impedance matching network. An example of a temperature sensor, as described herein, includes a thermocouple. An example of the switch system 224 includes one or more switches, such as transistors. An example of a driver, as used herein, includes one or more transistors.

The gas box 214 houses multiple gas sources, such as a gas source 1 and a gas source 2. Also, the gas box 214 houses multiple valves, such as a valve 1 and a valve 2. The system 200 further includes a driver DRVR1 and another driver DRVR2. An RF coil 228 surrounds the portions 150 and 152 of the wall of the plasma chamber 110. The RF coil 228 has two turns.

The plasma reactor 202 includes a top portion 230, a middle portion 232, and the bottom portion 234. The top portion 230 is the plasma chamber 110. The middle portion 232 includes an outlet 236 including multiple holes, such as throughholes, and a showerhead 238. An example of the outlet 236 is a plate and an example of the showerhead 238 is a plate having multiple openings. The multiple holes of the outlet 236 extend from the inside volume 158 to a middle volume 240, which is located between the outlet 236 and the showerhead 238. The bottom portion 234 includes a substrate support 242, such as an electrostatic chuck (ESC). Within the substrate support 242, a heater system 244, such a heater element, is embedded. An example of a heater element is a resistor. The bottom portion 234 further includes a bottom volume 246 between the showerhead 238 and the substrate support 242.

The bottom portion 234 includes a bottom wall 248 and a side wall 250. The bottom wall 248 is horizontally oriented and the side wall 250 is vertically oriented. Within the side wall 250 is a hole 252. The hole 252 is horizontally oriented within the side wall 250.

The controller 204 is coupled to the RF generators 206 and 210. The source RF generator 206 is coupled to the match 208 and the bias RF generator 210 is coupled to the match 212. The match 208 is coupled to the RF coil 228. Also, the match 212 is coupled to a lower electrode embedded within the substrate support 242. For example, the lower electrode is located above or below the heater system 244. The controller 204 is also coupled to the switch system 224. The DC power supply 222 is coupled to the switch system 224, which is coupled to the heater system 244.

The gas source 1 is coupled to the valve 1, which is coupled to the gas line 102. For example, the valve 1 is connected between the gas source 1 and the gas line 102. Similarly, the gas source 2 is coupled to the valve 2 that is coupled to the gas line 106. For example, the valve 2 is connected between the gas source 2 and the gas line 106.

The temperature sensor 216 is coupled at a point on the gas line 102 and the temperature sensor 218 is coupled at a point on the gas line 106. For example, the temperature sensor 216 is physically in contact with the gas line 102 and the temperature sensor 218 is physically in contact with the gas line 106. The temperature sensor 220 is coupled to a connector 201, such as an outflow delivery line or a pipe, which connects the opening 252 via the valve 228 to the vacuum pump 226. The temperature sensors 216, 218, and 220 are coupled to the controller 204. The valve 228 is coupled to the hole 252 and to the vacuum pump 226 via the connector 202. The valve 228 is coupled to the driver 227, which is coupled to the controller 204. The controller 204 is also coupled to the drivers DRVR1 and DRVR2, the driver DRVR1 is coupled to the valve 1, and the driver DRVR2 is coupled to the valve 2.

The process gas 166 is stored in the gas source 1 and the process gas 168 is stored in the gas source 2. A substrate S is placed on a top surface of the substrate support 242 for processing, such as etching the substrate S, or depositing materials on the substrate S, or cleaning the substrate S, or a combination thereof. After the substrate S is received within the bottom volume 246 of the plasma reactor 202 to be placed on the substrate support 242, the controller 204 sends an open control signal to the driver 227. Upon receiving the open control signal from the controller 204, the driver 227 generates and sends a current signal to the valve 228 to open the valve 228. The vacuum pump 226 is turned on to create a vacuum within the plenum 114, the inside volume 158, the middle volume 240, and bottom volume 246.

After the vacuum is created within the plenum 114, the inside volume 158, the middle volume 240, and bottom volume 246, the controller 204 controls the valve 228 to close. For example, the controller 204 sends a close control signal to the driver 227. Upon receiving the close control signal from the controller 204, the driver 227 generates and sends a current signal to the valve 228 to close the valve 228.

Moreover, after the vacuum is created in the inside volume 158, the middle volume 240, and bottom volume 246 and the valve 228 is closed, the controller 204 controls one or both of the valves 1 and 2 to control supply of one or both the process gases 166 and 168. For example, the controller 204 sends an open control signal to the driver DRVR1 and another open control signal to the driver DRVR2 to enable concurrent flow of the process gases 166 and 168. Upon receiving the open control signal, the driver DRVR1 generates an open current signal and sends the open current signal to the valve 1 to open the valve 1. Similarly, in response to receiving the open control signal, the driver DRVR2 generates a current signal and sends the current signal to the valve 2 to open the valve 2. When the valves 1 and 2 are open, the process gas 166 flows from the gas source 1 via the valve 1 and the gas line 102 to the top portion 114A of the plenum 114 simultaneously with a flow of the process gas 168 from the gas source 2 via the valve 2 and the gas line 106 to the top portion 114A. To illustrate, the process gas 166 is transferred via the gas line 102 and the process gas 168 is transferred via the gas line 106 simultaneously, such as during the same time period.

As another example, the controller 204 sends a close control signal to the driver DRVR1 and the open control signal to the driver DRVR2 to enable pulsed or staggered flow of the process gases 166 and 168. Upon receiving the close control signal, the driver DRVR1 generates a close current signal and sends the close current signal to the valve 1 to close the valve 1. When the valve 1 is closed, the gas 166 does not flow from the gas source 1 via the valve 1 and the gas line 102 to the top portion 114A of the plenum 114. To illustrate, the process gas 166 is transferred via the gas line 102 intermittently and the process gas 168 is transferred via the gas line 106 intermittently. To further illustrate, the process gas 166 is transferred via the gas line 102 during a different time period than a time period in which the process gas 168 is transferred via the gas line 106. As another further illustration, during a time period in which the process gas 168 is transferred via the gas line 106, the process gas 166 is not transferred via the gas line 102.

As yet another example, the controller 204 sends the open control signal to the driver DRVR1 and a close control signal to the driver DRVR2 to enable pulsed or staggered flow of the process gases 166 and 168. Upon receiving the close control signal, the driver DRVR2 generates a close current signal and sends the close current signal to the valve 2 to close the valve 2. When the valve 2 is closed, the gas 168 does not flow from the gas source 2 via the valve 2 and the gas line 106 to the top portion 114A of the plenum 114. To illustrate, during a time period in which the process gas 166 is transferred via the gas line 102, the process gas 168 is not transferred via the gas line 106. As still another example, the controller 204 sends the close control signal to the driver DRVR1 and the close control signal to the driver DRVR2 to close the valves 1 and 2.

During a time period in which the process gas 166 is supplied from the gas source 1 via the valve 1 and the gas line 102 to the top portion 114A of the plenum 114, the temperature sensor 216 measures a temperature of the process gas 166 to generate a measurement signal S1 and sends the measurement signal S1 to the controller 204. Upon receiving the measurement signal S1, the controller 204 identifies the temperature of the process gas 166 from the measurement signal S1 and determines whether the temperature is within a first predetermined temperature range, which is stored in the memory device of the controller 204. To further illustrate, the first predetermined range ranges between 26 degrees centigrade (° C.) and 27° C., such as between 26.5° C. and 27° C. In response to determining that the temperature is within the first predetermined temperature range, the controller 204 does not control the valve 1 via the driver DRVR1 to turn off the supply of the process gas 166. For example, the controller 204 does not send the close control signal to the valve 1 to close the valve 1 and the valve 1 remains open. On the other hand, upon determining that the temperature of the process gas 166 is not within, such as outside, the first predetermined temperature range, the controller 204 controls the valve 1 via the driver DRVR1 to turn off the supply of the process gas 166 to the top portion 114A. For example, the controller 204 sends the close control signal to the valve 1 to close the valve 1. The closing of the valve 1 protects the plasma reactor 202 from being damaged by the temperature of the process gas 166.

Similarly, during a time period in which the process gas 168 is supplied from the gas source 2 via the valve 2 and the gas line 106 to the top portion 114A of the plenum 114, the temperature sensor 218 measures a temperature of the process gas 168 to generate a measurement signal S2 and sends the measurement signal S2 to the controller 204. Upon receiving the measurement signal S2, the controller 204 identifies the temperature of the process gas 168 from the measurement signal S2 and determines whether the temperature is within a second predetermined temperature range.

The second predetermined temperature range is stored in the memory device of the controller 204. As an example, the second predetermined temperature range is the same as, such as equal to, the first predetermined temperature range. To illustrate, the second predetermined temperature range has the same upper limit as that of the first predetermined temperature range and the same lower limit as that of the first predetermined temperature range. To further illustrate, the second predetermined range ranges between 26° C. and 27° C. As another example, the second predetermined temperature range is different from the first predetermined temperature range. To illustrate, the second predetermined temperature range has a different upper limit from that of the first predetermined temperature range or a different lower limit from that of the first predetermined temperature range or has the different upper and lower limits. To further illustrate, the second predetermined range ranges between 26.4° C. ad 26.8° C.

In response to determining that the temperature is within the second predetermined temperature range, the controller 204 does not control the valve 2 via the driver DRVR2 to turn off the supply of the process gas 168. For example, the controller 204 does not send the close control signal to the valve 2 to close the valve 2 and the valve 2 remains open. On the other hand, upon determining that the temperature of the process gas 168 is not within, such as outside, the second predetermined temperature range, the controller 204 controls the valve 2 via the driver DRVR2 to turn off the supply of the process gas 168 to the top portion 114A. For example, the controller 204 sends the close control signal to the valve 2 to close the valve 2. The closing of the valve 2 protects the plasma reactor 202 from being damaged by the temperature of the process gas 168.

It should be noted that when the process gases 166 and 168 mix with each other under the atmospheric pressure, due to the release of the large amount of heat, a temperature sensor (not shown), such as the temperature sensor 216 or 218, measures temperature of the heat to generate a measurement signal. Upon receiving the measurement signal from the temperature sensor (not shown), the controller 204 compares the temperature of the heat with the first predetermined range or the second predetermined range or both the first and second predetermined ranges. Based on the comparison, the controller 204 determines that the temperature of the heat output from the exothermic reaction is outside the first predetermined range and the second predetermined range. For example, the temperature of the heat output is greater than the temperatures of the process gas 166 flowing via the gas line 102 and the process gas 168 flowing via the gas line 106. To illustrate, the temperature of the heat output is greater than the temperatures of the process gas 166 flowing via the gas line 102 and the process gas 168 flowing via the gas line 106 by at least nine degrees centigrade, such as by 10° C. or 11° C.

Also, after the vacuum is created in the plenum 114, the inside volume 158, the middle volume 240, and bottom volume 246, the controller 204 controls the switch system 224 to connect the DC power supply 222 to the heater system 244. When the switch system 224 connects the DC power supply 222 to the heater system 244, DC power is supplied from the DC power supply 222 to the heater system 244.

During a time period in which the plenum 114, the inside volume 158, the middle volume 240, and bottom volume 246 are under vacuum, one or more of the process gases 166 and 168 flow from the top portion 114A to the bottom portion 114B of the plenum 114, and pass via the openings 162 of the diffuser 108 into the inside volume 158 of the plasma chamber 110. Also, during a time period in which the plenum 114, the inside volume 158, the middle volume 240, and bottom volume 246 are under vacuum, one or more of the process gases 166 and 168 flow from the inside volume 158 to the middle volume 240 via the throughholes of the outlet 236. Furthermore, during a time period in which the plenum 114, the inside volume 158, the middle volume 240, and bottom volume 246 are under vacuum, one or more of the process gases 166 and 168 flow from the middle volume 240 to the bottom volume 246 to process the substrate S.

After the substrate S is processed, the controller 204 sends the open control signal to the valve 228 to open the valve 228. When the valve 228 is open, remnants of processing the substrate S exit from the bottom volume 246 via the opening 252 and the valve 228 to the vacuum pump 226 to be removed from the plasma reactor 202. Examples of remnants of processing the substrate S include one or more of the process gases 166 and 168, one or more materials etched from the substrate S, and a combination of the one or more of the process gases 166 and 168 and the one or more materials etched from the substrate S. To illustrate, the one or more materials etched from the substrate S include a material, such as Silicon Germanium (SiGe) or Silicon nitride (Si₃N₄), of a stack layer of the substrate S.

During the time period in which the valve 228 is open to remove the remnants of processing the substrate S, the temperature sensor 220 measures the temperature of the remnants to generate a measurement signal S3, and sends the measurement signal S3 to the controller 204. In response to receiving the measurement signal S3, the controller 204 identifies the temperature of the remnants from the measurement signal S3 and determines whether the temperature of the remnants is within a third predetermined range.

The third predetermined range is stored in the memory device of the controller 204. As an example, the third predetermined range is equal to the first predetermined range or the second predetermined range or both the first and second predetermined ranges. To illustrate, the third predetermined range has an upper limit that is equal to the upper limit of the first predetermined range and the upper limit of the second predetermined range. Further, in the illustration, the third predetermined range has a lower limit that is equal to the lower limit of the first predetermined range and the lower limit of the second predetermined range to be equal to the first predetermined range and the second predetermined range. To further illustrate, the third predetermined range ranges between 26° C. and 27° C. As another example, the third predetermined range is different from the first and second predetermined ranges. To illustrate, the third predetermined range has an upper limit that is greater than the upper limit of the first predetermined range and the upper limit of the second predetermined range or has a lower limit that is lower than the lower limit of the first predetermined range and the lower limit of the second predetermined range or a combination thereof. To further illustrate, the third predetermined range ranges between 26.3° C. ad 26.9° C.

Upon determining that the temperature of the remnants is within the third predetermined temperature range, the controller 204 does not control the valve 228 to close. For example, the controller 204 does not send the close control signal to the valve 228 to close the valve 228. On the other hand, upon determining that the temperature of the remnants is not within, such as outside, the third predetermined temperature range, the controller 204 controls the valve 228 to close. The closing of the valve 228 protects the vacuum pump 226 from being damaged.

It should be noted that thermal processing of the substrate S occurs when the RF generators 206 and 210 are not operated. For example, when the DC power supply 222 supplies the DC power to the heater system 244 to process the substrate S without supplying RF power to the RF coil 228 and without supplying RF power to the substrate support 242, the substrate S is thermally processed. There is no plasma generated in the bottom volume 246 during the thermal processing.

In one embodiment, the gas box 214 includes any number of gas sources and the same number of valves. For example, the gas box 214 includes n number of gas sources and n number of valves, where n is a positive integer.

In an embodiment, the RF coil 228 has more than two turns, such as three or four turns surrounding the portions 150 and 152 of the wall of the plasma chamber 110.

In one embodiment, the substrate support 242 includes multiple heater elements, and each heater element is coupled via a respective switch system to a respective DC power supply. The switch systems are coupled to the controller 204.

In an embodiment, the temperature sensor 216 is coupled to a connection between the gas source 1 and the valve 1 and the temperature sensor 218 is coupled to a connection between the gas source 2 and the valve 2.

In an embodiment, the temperature sensor 216 is connected to the clamp 136 to measure a temperature of the process gas 166 flowing from the gas line 102 to the top portion 114A via the hole 140, and the temperature sensor 218 is connected to the clamp 148 to measure a temperature of the process gas 168 flowing from the gas line 106 to the top portion 114A via the hole 142.

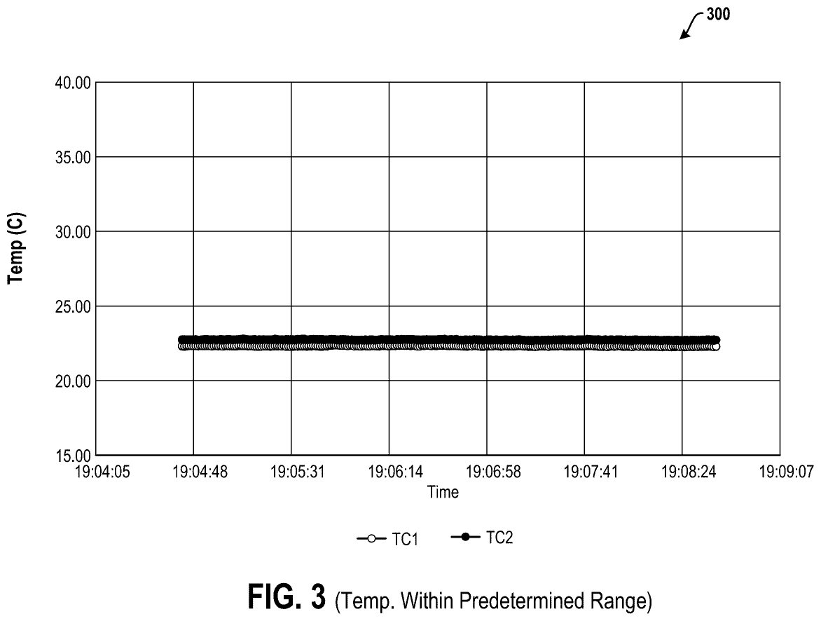

FIG. 3 is an embodiment of a graph 300 to illustrate the first and second predetermined ranges. The graph 300 plots temperatures of the process gases 166 and 168 (FIG. 1) on a Y-axis and time on an X-axis. An example of the first predetermined range is a range between 26 degrees ° C. and 27° C., and an example of the second predetermined range is arranged between 26° C. and 27° C. To illustrate, the first predetermined range is between 26.5° C. and 26.95° C., and the second predetermined range is between 26.4° C. and 26.8° C. By supplying the process gas 166 via the gas line 102 (FIG. 1) and the process gas 160 via the gas line 106 (FIG. 1), the temperature of the process gas 166 is controlled to be within the first predetermined range and the temperature of the process gas 168 is controlled to be within the second predetermined range.

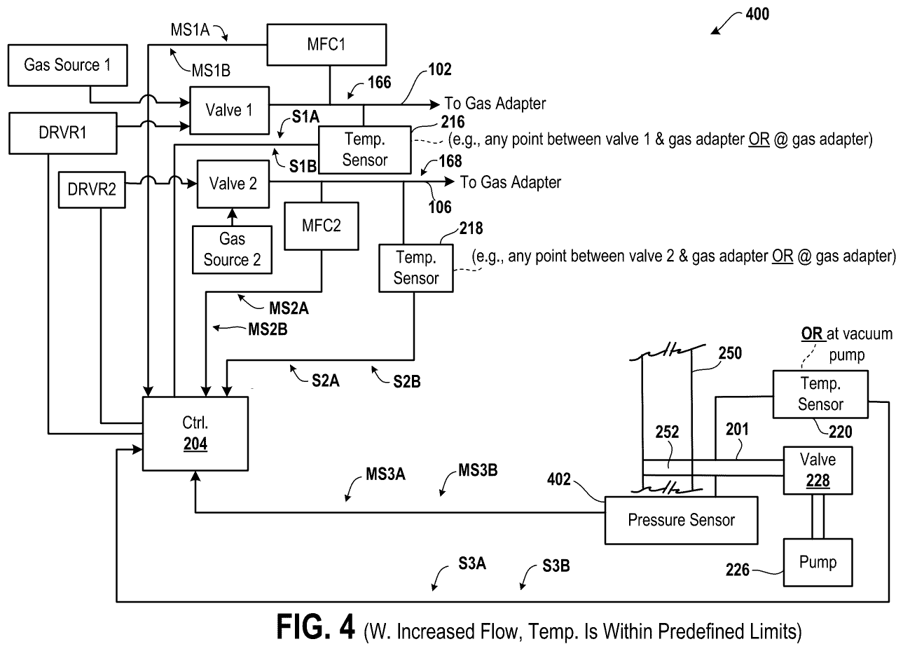

FIG. 4 is a diagram of an embodiment of a system 400 to illustrate that the temperature of the process gas 166 is maintained to be within the first predetermined range with an increase in a flow of the process gas 166 from the gas source 1 (FIG. 2) to the top portion 114A (FIG. 1) of the plenum 114 and the temperature of the process gas 166 is maintained to be within the second predetermined range with an increase in a flow of the process gas 168 from the gas source 2 (FIG. 2) to the top portion 114A (FIG. 1) of the plenum 114. The system 400 includes the gas sources 1 and 2, the drivers DRVR1 and DRVR2, the valves 1 and 2, a mass flow controller MFC1, another mass flow controller MFC2, the temperature sensors 216 and 218, the controller 204, the valve 228, the temperature sensor 220, and a pressure sensor 402. As an example, a mass flow controller includes a flow rate meter. The mass flow controllers MFC1 and MFC2 are coupled to the controller 204. Also, the pressure sensor 402 is coupled to the controller 204 and to the connector 201.

During the time period in which the valve 1 is open to supply the process gas 166 via the gas line 102 to the top portion 114A (FIG. 1) of the plenum 114, the mass flow controller MFC1 measures, during a first time period, a first flow rate of flow of the process gas 166 in the gas line 102 to generate a measurement signal MS1A and sends the measurement signal MS1A to the controller 204. The controller 204 identifies from the measurement signal MS1A, the first flow rate of the flow of the process gas 166. Also, the temperature sensor 216 measures, during the first time period, a first temperature of the process gas 166 in the gas line 102 to generate a measurement signal SIA and sends the measurement signal SIA to the controller 204.

Moreover, the mass flow controller MFC1 measures, during a second time period, a second flow rate of flow of the process gas 166 in the gas line 102 to generate a measurement signal MS1B and sends the measurement signal MS1B to the controller 204. As an example, the second time period occurs after the first time period. Also as an example, the second flow rate of the process gas 166 is greater than the first flow rate of the process gas 166 to be a progressively increasing flow rate compared to the first flow rate. To illustrate, the second flow rate is 800 standard cubic centimeters per minute (sccm) and the first flow rate is 400 sccm. As another illustration, the second flow rate is 1200 sccm and the first flow rate is 800 sccm. As yet another illustration, the second flow rate is 2000 sccm and the first flow rate is 1200 sccm. As another example, the second flow rate is less than the first flow rate to be a progressively decreasing flow rate compared to the first flow rate. The controller 204 identifies from the measurement signal MS1B, the second flow rate of the flow of the process gas 166. Also, the temperature sensor 216 measures, during the second time period, a second temperature of the process gas 166 in the gas line 102 to generate a measurement signal S1B and sends the measurement signal S1B to the controller 204. As an example, the first temperature is equal to the second temperature. As another example, the first temperature is different from the second temperature.

The controller 204 receives the measurement signals MS1A and S1A during the first time period and the measurement signals MS1B and S1B during the second time period, identifies the first and second flow rates of the flows of the process gas 166, identifies the first and second temperatures of the process gas 166, and determines whether the first and second temperatures are within the first predetermined range with the progressive increase or the progressive decrease from the first flow rate to the second flow rate. Upon determining that the first and second temperatures are within the first predetermined range, the controller 204 does not control the valve 1 to close to stop the flow of the process gas 166 to the top portion 114A (FIG. 1). On the other hand, in response to determining that the first temperature is or the second temperature is or both the first and second temperatures are outside the first predetermined range, the controller 204 controls the valve 1 to close to prevent the flow of the process gas 166 to the top portion 114A. In this manner, the controller 204 receives further flow rates from the mas flow controller MFC1 and further temperature values from the temperature sensor 216, and determines whether to control the valve 1.

Similarly, during the time period in which the valve 2 is open to supply the process gas 168 via the gas line 106 to the top portion 114A of the plenum 114, the mass flow controller MFC2 measures, during a primary time period, a primary flow rate of flow of the process gas 168 in the gas line 106 to generate a measurement signal MS2A and sends the measurement signal MS2A to the controller 204. As an example, the primary time period occurs simultaneously with the first time period. As another example, the primary time period occurs before, such as immediately before, or after, such as consecutive to or immediately following, the first time period. The controller 204 identifies from the measurement signal MS2A, the primary flow rate of the flow of the process gas 168. Also, the temperature sensor 216 measures, during the primary time period, a primary temperature of the process gas 168 in the gas line 106 to generate a measurement signal S2A and sends the measurement signal S2A to the controller 204.

Moreover, the mass flow controller MFC2 measures, during a secondary time period, a secondary flow rate of flow of the process gas 168 in the gas line 106 to generate a measurement signal MS2B and sends the measurement signal MS2B to the controller 204. As an example, the secondary time period occurs after the primary time period. Also as an example, the secondary flow rate of the process gas 168 is greater than the primary flow rate of the process gas 168 to be a progressively increasing flow rate compared to the primary flow rate. To illustrate, the secondary flow rate is 200 sccm and the primary flow rate is 100 sccm. As another illustration, the secondary flow rate is 300 sccm and the primary flow rate is 200 sccm. As yet another illustration, the secondary flow rate is 500 sccm and the first flow rate is 300 sccm. As another example, the secondary flow rate is less than the primary flow rate to be a progressively decreasing flow rate compared to the primary flow rate. As an example, the secondary time period occurs simultaneously with the second time period. As another example, the secondary time period occurs before, such as immediately before, or after, such as consecutive to or immediately following, the second time period.

The controller 204 identifies from the measurement signal MS2B, the secondary flow rate of the flow of the process gas 168. Also, the temperature sensor 216 measures, during the secondary time period, a secondary temperature of the process gas 168 in the gas line 106 to generate a measurement signal S2B and sends the measurement signal S2B to the controller 204. As an example, the primary temperature is equal to the secondary temperature. As another example, the primary temperature is different from the secondary temperature.

The controller 204 receives the measurement signals MS2A and S2A during the primary time period and the measurement signals MS2B and S2B during the secondary time period, identifies the primary and secondary flow rates of the flows of the process gas 168, identifies the primary and secondary temperatures of the process gas 168, and determines whether the primary and secondary temperatures are within the second predetermined range with the progressive increase or the progressive decrease from the primary flow rate to the secondary flow rate. Upon determining that the primary and secondary temperatures are within the second predetermined range, the controller 204 does not control the valve 2 to close to stop the flow of the process gas 168 to the top portion 114A (FIG. 1). On the other hand, in response to determining that the primary temperature is or the secondary temperature is or both the primary and secondary temperatures are outside the second predetermined range, the controller 204 controls the valve 2 to close to prevent the flow of the process gas 168 to the top portion 114A. In this manner, the controller 204 receives further flow rates from the mas flow controller MFC2 and further temperature values from the temperature sensor 218, and determines whether to control the valve 2.

Also, during the time period in which the valve 228 is open to transfer the remnants of thermal processing from the plasma reactor 202 (FIG. 2) to the vacuum pump 226, the pressure sensor 402 measures, during a first time interval, a first amount of pressure of flow of the remnants via the opening 252 and the connector 201 to the vacuum pump 226 (FIG. 2) to generate a measurement signal MS3A and sends the measurement signal MS3A to the controller 204.

The controller 204 identifies from the measurement signal MS3A, an initial flow rate of the flow of the remnants. For example, the controller 204 identifies from the measurement signal MS3A, the first amount of pressure. Further, in the example, the controller 24 determines from correspondences, such as one to one relationships, between amounts of pressures of flow of the remnants and amounts of flow rates stored in the memory device of the controller 204, that the first amount of pressure corresponds to the initial flow rate. To illustrate, the controller 204 determines that the first amount of pressure has a one-to-one relationship with the initial flow rate. Also, the temperature sensor 252 measures, during the first time interval, an initial temperature of the remnants flowing via the opening 252 and the connector 201 to the vacuum pump 226 to generate a measurement signal S3A and sends the measurement signal S3A to the controller 204.

Moreover, the pressure sensor 402 measures, during a second time interval, a second amount of pressure of flow of the remnants via the opening 252 and the connector 201 to the vacuum pump 226 to generate a measurement signal MS3B and sends the measurement signal MS3B to the controller 204. As an example, the second time interval occurs after the primary time interval. Also as an example, the second amount of pressure of flow of the remnants is greater than the first flow amount of pressure of flow of the remnants. As another example, the second amount of pressure of flow is less than the first amount of pressure of flow.

The controller 204 identifies from the measurement signal MS3B, a final flow rate of the flow of the remnants. For example, the controller 204 identifies from the measurement signal MS3B, the second amount of pressure. Further, in the example, the controller 204 determines from the correspondences, such as one to one relationships, between amounts of pressures of flow of the remnants and amounts of flow rates stored in the memory device of the controller 204, that the second amount of pressure corresponds to the final flow rate. To illustrate, the controller 204 determines that the second amount of pressure has a one-to-one relationship with the final flow rate. Also, the temperature sensor 252 measures, during the second time interval, a final temperature of the remnants flowing within the opening 252 to generate a measurement signal S3B and sends the measurement signal S3B to the controller 204.

The controller 204 receives the measurement signals MS3A and S3A during the first time interval and the measurement signals MS3B and S3B during the second time interval, determines the initial and final flow rates of the flows of the remnants, identifies the initial and final temperatures of the remnants, and determines whether the initial and final temperatures are within the third predetermined range with an increase from the initial flow rate to the final flow rate. Upon determining that the initial and final temperatures are within the third predetermined range, the controller 204 does not control the valve 228 to close to stop the flow of the remnants to the vacuum pump 226. On the other hand, in response to determining that the initial temperature or the final temperature or a combination thereof is outside the third predetermined range, the controller 204 controls the valve 228 to close to prevent the flow of the remnants to the vacuum pump 226.

In an embodiment, a temperature sensor (not shown), such as the temperature sensor 220, is coupled to the vacuum pump 226. The temperature sensor (not shown) is coupled to the controller 204 and generates measurement signals of temperatures at the vacuum pump 226 as flow rates of the process gases 166 and 168 progressively change, such as progressive increase or progressively decrease. The temperature sensor (not shown) sends the measurement signals to the controller 204. Upon receiving the measurement signals, the controller 204 determines whether the temperatures are within a fourth predetermined range, which is greater than the first, second, and third predetermined ranges. An example of the fourth predetermined range is a range from 74° C. and 79° C. Upon determining that the temperatures are within the fourth predetermined range, the controller 204 does not control the vacuum pump 226 via a switch, such as a driver, to turn off. The controller 204 is coupled to the vacuum pump 226 via the switch. On the other hand, upon determining that the temperatures are outside the fourth predetermined range, the controller 204 controls the vacuum pump 226 via the switch to turn off to protect the vacuum pump 226.

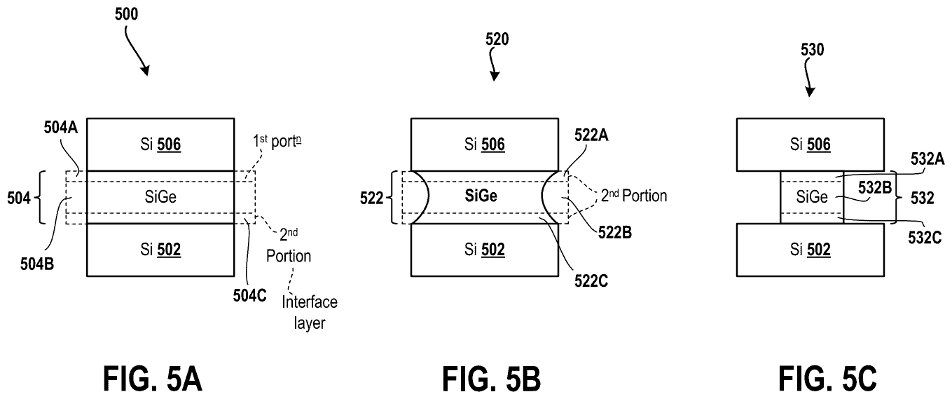

FIG. 5A is a diagram of an embodiment of a substrate 500 before the substrate 500 is thermally processed using the plasma system 200 (FIG. 2). The substrate 500 is an example of the substrate S before the thermal processing. The substrate 500 includes multiple stack layers, such as a Silicon (Si) layer 502, a Silicon Germanium layer 504, and another Silicon layer 506. Each layer 502, 504, and 506 is an example of a stack layer. The Silicon Germanium layer 504 is stacked or sandwiched between the two Silicon layers 502 and 506. For example, the silicon germanium layer 504 is located above the silicon layer 502 and the silicon layer 506 is located above the silicon germanium layer 504. The silicon germanium layer 504 has a top portion 504A, a middle portion 504B, and a bottom portion 504C. The top portion 504A interfaces with, such as is adjoining to, to the silicon layer 506, and the bottom portion 504C interfaces with the silicon layer 502. The middle portion 504B is sometimes referred to herein as a first portion and a combination of the top portion 504A and the bottom portion 504C is sometimes referred to herein as a second portion. As an example, the first portion has a higher concentration of Germanium (Ge) compared to Silicon (Si) to be referred to herein as a bulk Silicon Germanium layer and the second portion is a higher concentration of Silicon compared to Germanium to be referred to herein as an interface Silicon Germanium layer. To illustrate, the first portion as a high percentage of Germanium compared to silicon and the second portion has a higher percentage of Silicon compared to Germanium.

FIG. 5B is a diagram of an embodiment of a substrate 520 to illustrate etching of the substrate 500 (FIG. 5A) by using the process gas 166 (FIG. 1), such as the Fluorine-containing gas. The substrate 520 is an example of the substrate S after being processed by the process gas 166. The substrate 520 includes the Silicon layers 502 and 506, and a Silicon Germanium layer 522 is between the silicon layers 502 and 506. For example, the Silicon Germanium layer 522 is located above the Silicon layer 502 and the Silicon layer 506 is located above the Silicon Germanium layer 522.

The Silicon Germanium layer 522 has a top portion 522A, a middle portion 522B, and a bottom portion 522C. The top portion 522A interfaces with, such as is adjoining to, to the silicon layer 506, and the bottom portion 522C interfaces with the silicon layer 502. The middle portion 522B is sometimes referred to herein as a first portion after being processed by the process gas 166 and a combination of the top portion 522A and the bottom portion 522C is sometimes referred to herein as a second portion after being processed by the process gas 166.

Because the top portion 522A and the bottom portion 522C has the higher concentration of Silicon compared to Germanium, the top and bottom portions 522A and 522C are etched in lesser amounts when the process gas 166 is applied to the substrate 520 compared to the middle portion 522B. The process gas 166 etches the middle portion 522B in a maximum amount compared to the top and bottom portions 522A and 522C to form concavities on sides of the Silicon Germanium layer 522.

FIG. 5C is a diagram of an embodiment of a substrate 530 to illustrate etching of the substrate 520 (FIG. 5B) by using the gas mixture 170 (FIG. 1) of the process gases 166 and 168 (FIG. 1). The substrate 530 is an example of the substrate S after being processed by the gas mixture 170. The substrate 530 includes the Silicon layers 502 and 506, and a Silicon Germanium layer 532 is located between the silicon layers 502 and 506. For example, the Silicon Germanium layer 532 is located above the Silicon layer 502 and the Silicon layer 506 is located above the Silicon Germanium layer 532.

The Silicon Germanium layer 532 has a top portion 532A, a middle portion 532B, and a bottom portion 532C. The top portion 532A interfaces with, such as is adjoining to, to the silicon layer 506, and the bottom portion 532C interfaces with the silicon layer 502. The middle portion 532B is sometimes referred to herein as a first portion after being processed by the gas mixture 170 and a combination of the top portion 532A and the bottom portion 532C is sometimes referred to herein as a second portion after being processed by the gas mixture 170.

Because the top portion 532A and the bottom portion 532C has the higher concentration of Silicon compared to Germanium and the middle portion 532B has the high concentration of Germanium compared to Silicon, all the portions 532A through 532C are etched in equal or substantially equal amounts when the gas mixture 170 is applied to the substrate 530. The application of the gas mixture 170 reduces, such as removes, the concavities.

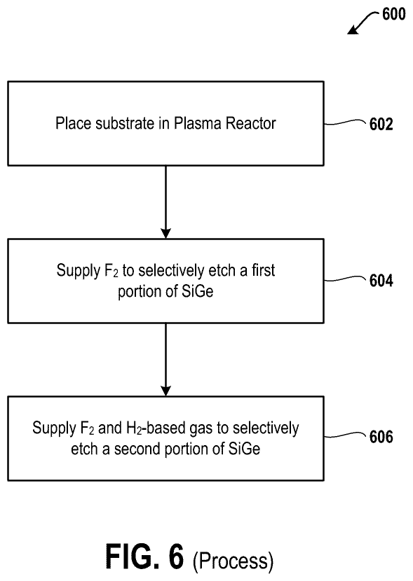

FIG. 6 is a flowchart of an embodiment of a method 600 to illustrate processing of the substrate S (FIG. 1) by applying the process gas 166 and the gas mixture 170 (FIG. 1) of the process gases 166 and 168. The method 600 is executed using the plasma system 200 (FIG. 2).

The method 600 includes an operation 602 in which the substrate S is placed within the bottom volume 246 (FIG. 2) of the plasma reactor 202. After vacuum is created within the plenum 114 and the volumes 158, 240, 246 (FIG. 2) of the plasma reactor 202, the method includes an operation 604 of supplying the process gas 166 (FIG. 1) to selectively etch the first portion of the substrate 500 (FIG. 5A). For example, the controller 204 controls the valve 1 to open and the valve 2 to close to supply the process gas 166 without supplying the process gas 168 to the top portion 114A (FIG. 1) of the plenum 114. The method 600 further includes an operation 606 of supplying the process gases 166 and 168 to the top portion 114A of the plenum 114. As an example, the controller 204 controls the valves 1 and 2 to open to supply the process gases 166 and 168 simultaneously to the top portion 114A of the plenum 114. For example, the process gas 166 is transferred from the gas line 102 via the opening 103 and the hole 140 into the top portion 114A during the same time period in which the process gas 168 is transferred from the gas line 106 via the opening 105 and the hole 142 into the top portion 114A. The process gases 166 and 168 are simultaneously supplied to selectively etch the second portion of the substrate 520 (FIG. 5B).

In one embodiment, the operations 604 and 606 are performed multiple times. For example, the operation 604 repeats after the operation 606, and after the operation 604 repeats, the operation 606 repeats.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller, described herein, is a part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a capacitively coupled plasma (CCP) chamber, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), read-only memory (ROM), random access memory (RAM), compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment described above are combined with one or more features of any other embodiment without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A system for supplying multiple gases to a plasma chamber, comprising:
a gas adapter having a body, a first hole formed inside the body, a second hole formed inside the body, and a plenum;
a first gas line coupled to the gas adapter at an opening of the first hole, wherein the first gas line is configured to transfer a first process gas to the plenum via the first hole;
a second gas line coupled to the gas adapter via an opening of the second hole, wherein the second gas line is configured to transfer a second process gas to the plenum via the second hole, wherein the first process gas is transferred via the first gas line and the second process gas is transferred via the second gas line while maintaining a first temperature of the first process gas to be within a first predetermined range and a second temperature of the second process gas to be within a second predetermined range, wherein the first and second temperatures are lower than a third temperature that is achieved by a mixture, at an atmospheric pressure, of the first process gas with the second process gas,
wherein the gas adapter is configured to mix the first process gas with the second process gas under vacuum to generate a gas mixture and to supply the gas mixture to an inside volume of the plasma chamber.

2. The system of claim 1, wherein the first gas line is configured to transfer the first process gas at a progressively increasing flow rate while maintaining the first temperature to be within the first predetermined range, and the second gas line is configured to transfer the second process gas at a progressively increasing flow rate while maintaining the second temperature to be within the second predetermined range.

3. The system of claim 1, wherein the first predetermined range is equal to the second predetermined range.

4. The system of claim 1, wherein the gas adapter is coupled to a vacuum pump via the plasma chamber of a plasma reactor, wherein the plasma reactor is configured to output remnants of the gas mixture, wherein the plasma reactor is configured to transfer the remnants to the vacuum pump while maintaining a fourth temperature of the remnants to be within a third predetermined range.

5. The system of claim 4, wherein the third predetermined range is equal to the first predetermined range or second predetermined range.

6. The system of claim 1, wherein the first gas line is coupled to the gas adapter via a fitting and a clamp, wherein the first hole is horizontally oriented with respect to the plenum and interfaces with the plenum and the first gas line, wherein the first hole is located between the first gas line and the plenum, wherein the first hole is configured to transfer the first process gas received from the first gas line to the plenum.

7. The system of claim 6, wherein the second gas line is coupled to the gas adapter via a fitting and a clamp, wherein the second hole is horizontally oriented with respect to the plenum, interfaces with the plenum, and is coupled to the second gas line, wherein the second hole is located between the second gas line and the plenum, wherein the second hole is configured to transfer the second process gas received from the second gas line to the plenum.

8. The system of claim 1, wherein the first process gas is reactive with the second process gas at the atmospheric pressure to produce an exothermic reaction, wherein the first process gas is Fluorine and the second process gas is a hydrogen-based gas.

9. The system of claim 8, wherein the hydrogen-based gas is a hydrogen gas, or methane gas, or a gas containing hydrogen.

10. The system of claim 1, wherein the plenum has a vacuum during reception of the first and second process gases and transfer of the first and second process gases.

11. The system of claim 1, wherein the third temperature is outside the first predetermined range and the second predetermined range.

12. The system of claim 1, wherein the first temperature is measured at the first gas line, and the second temperature is measured at the second gas line.

13. A method for supplying multiple gases to a plasma reactor for processing a substrate, comprising:
receiving a first process gas from a first gas line, wherein the first process gas is received by a gas adapter coupled to the first gas line;
transferring the first process gas from the gas adapter via a diffuser to a volume of the plasma reactor;
obtaining, the first process gas from the first gas line and a second process gas from a second gas line after said receiving the first process gas via the first gas line, wherein the first process gas is obtained via the first gas line and the second process gas is obtained via the second gas line by the gas adapter coupled to the second gas line, wherein the first process gas is obtained from the first gas line and the second process gas is obtained from the second gas line while simultaneously maintaining a first temperature of the first process gas and a second temperature of the second process gas to be within a first predetermined range, wherein the first and second temperatures are lower than a third temperature that is achieved by mixing, at an atmospheric pressure, the first process gas with the second process gas;
mixing, within the gas adapter, the first and second process gases under vacuum to generate a gas mixture;
supplying the gas mixture from the gas adapter via the diffuser to the volume of the plasma reactor to process the substrate.

14. The method of claim 13, further comprising:
receiving, via the first gas line, the first process gas at a progressively increasing flow rate while maintaining the first temperature to be within the first predetermined range; and
receiving, via the second gas line, the second process gas at a progressively increasing flow rate while maintaining the second temperature to be within the first predetermined range.

15. The method of claim 13, wherein the gas adapter is coupled to a vacuum pump via the plasma reactor, the method further comprising:
transferring the remnants to the vacuum pump while maintaining a fourth temperature of the remnants to be within a second predetermined range.

16. The method of claim 13, wherein the substrate comprises a Silicon Germanium layer that interfaces with a Silicon layer.

17. The method of claim 13, further comprising receiving, by a heater element of the plasma reactor, a direct current (DC) signal generated by a DC power supply to process the substrate.

18. The method of claim 13, wherein the first process gas is reactive with the second process gas under the atmospheric pressure to produce an exothermic reaction, wherein the first gas line is coupled to the gas adapter via a fitting and a clamp, the first process gas is Fluorine, and the second process gas is a hydrogen-based gas.

19. A plasma system for controlling a supply of multiple gases to a plasma chamber, comprising:
a gas box;
a gas adapter;
a first gas line coupled to the gas adapter and to the gas box, wherein the first gas line is configured to transfer a first process gas;
a second gas line coupled to the gas adapter and to the gas box, wherein the second gas line is configured to transfer a second process gas, wherein the first process gas is transferred via the first gas line and the second process gas is transferred via the second gas line while maintaining a first temperature of the first process gas and a second temperature of the second process gas to be within a predetermined range, wherein the first and second temperatures are lower than a third temperature that is achieved by a mixture, at an atmospheric pressure, of the first process gas with the second process gas,
wherein the gas adapter is configured to mix the first process gas with the second process gas under vacuum to generate a gas mixture and to supply the gas mixture to an inside volume of the plasma chamber.

20. The plasma system of claim 19, wherein the first process gas is reactive with the second process gas to produce an exothermic reaction under the atmospheric pressure, wherein the gas adapter is located above the inside volume, wherein the first gas line is configured to transfer the first process gas at a progressively increasing flow rate while maintaining the first temperature to be within the predetermined range, and the second gas line is configured to transfer the second process gas at a progressively increasing flow rate while maintaining the second temperature to be within the predetermined range.
